(19) United States
(12) Patent Application Publication
(10) Pub. No.: US 2026/0026316 A1
(43) Pub. Date: Jan. 22, 2026

(54) Device and Method for Verifying Characteristics of Semiconductor Chips

(71) Applicant: Taiwan Semiconductor Manufacturing Company, Ltd., Hsinchu (TW)

(72) Inventor: Tung-Tsun Chen, Hsinchu (TW)

(21) Appl. No.: 18/779,324

(22) Filed: Jul. 22, 2024

(51) Int. Cl. H01L 21/66; H01L 27/085

(52) U.S. Cl. CPC H10P 74/277; H10D 84/82

(57) ABSTRACT

A device includes a plurality of semiconductor chips, a device under test (DUT) circuit, a control circuit, and a switch circuit. The semiconductor chips are fabricated on a semiconductor wafer that includes one or more scribe lines. The DUT circuit is formed along at least one of the scribe lines and includes a plurality of DUTs. The switch circuit is connected between the DUT circuit and the control circuit. The control circuit generates a plurality of control signals. The switch circuit connects the DUTs to a test probe pad one at a time in response to the control signals. A method for verifying characteristics of the semiconductor chips is also disclosed.

### BACKGROUND

Semiconductor chips (dies or integrated circuits), such as those fabricated on a semiconductor wafer, may be defined by scribe lines provided on the semiconductor wafer. A scribe line is a demarcation between an adjacent pair of the semiconductor chips. The scribe lines may be narrow, shallow channels or grooves etched onto the surface of the semiconductor wafer during the fabrication of the semiconductor chips. These channels penetrate a fraction of the thickness of the semiconductor wafer. After the fabrication process, the semiconductor wafer is diced (or is cut along the scribe lines) to physically separate the semiconductor chips.

### BRIEF DESCRIPTION OF THE DRAWINGS

Aspects of the present disclosure are best understood from the following detailed description when read with the accompanying figures:

FIG. 1 is a schematic block diagram illustrating an exemplary device in accordance with various embodiments of the present disclosure;

FIG. 2 is a schematic block/circuit diagram illustrating another exemplary device in accordance with various embodiments of the present disclosure;

FIG. 3 is a schematic block/circuit diagram illustrating another exemplary device in accordance with various embodiments of the present disclosure;

FIG. 4 is a schematic structure diagram illustrating another exemplary device in accordance with various embodiments of the present disclosure;

FIG. 5 is a schematic structure diagram illustrating another exemplary device in accordance with various embodiments of the present disclosure;

FIG. 6 is a schematic structure diagram of exemplary core circuits in accordance with various embodiments of the present disclosure;

FIG. 7 is a flowchart of an exemplary method of verifying the characteristics of semiconductor chips using a device in accordance with various embodiments of the present disclosure; and

FIG. 8 is a flowchart of another exemplary method of verifying the characteristics of semiconductor chips using a device in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A device includes a semiconductor wafer, a plurality of semiconductor chips (dies or integrated circuits) fabricated on the semiconductor wafer, and a plurality of scribe lines that are provided on the semiconductor wafer and that each serve as a demarcation between an adjacent pair of the semiconductor chips. As noted above, the scribe lines may be narrow, shallow channels or grooves etched onto the surface of the semiconductor wafer during fabrication of the semiconductor chips. These channels penetrate a fraction of the thickness of the semiconductor wafer. During the fabrication process, a device under test (DUT) circuit that includes one or more DUTs may be formed along (within or extending beyond) at least one of the scribe lines. The DUT circuit can be used to verify the characteristics (e.g., mismatches) of the semiconductor chips. After the verification process, the semiconductor wafer is diced (or is cut along the scribe lines), ruining the DUT circuit, to physically separate the semiconductor chips.

An example DUT circuit may include a large number of test probe pads that serve as contact points for test probes during a verification process. Such a large number of test probe pads may occupy a significant amount of space and can make the verification process cumbersome. Certain systems and methods, as described herein, minimize the number of test probe pads by employing a switch circuit that permits sharing of a test probe pad among the DUTs, in a manner that will be described in detail hereinafter.

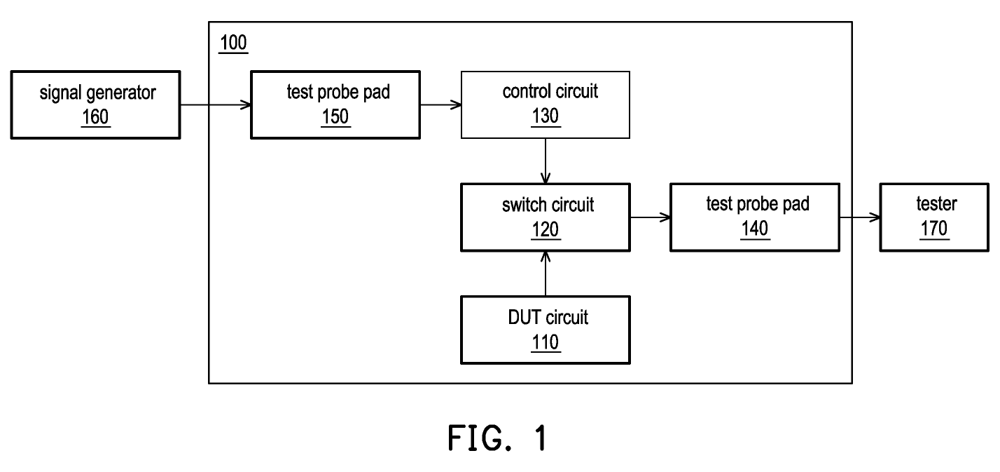

FIG. 1 is a schematic block diagram illustrating an exemplary device 100 in accordance with various embodiments of the present disclosure. As illustrated in FIG. 1, the example device 100 includes a DUT circuit 110, a switch circuit 120, and a control circuit 130. The device 100 may be fabricated along (within and/or extending beyond) one or more scribe lines of a semiconductor wafer. The semiconductor wafer includes a plurality of semiconductor chips (dies or integrated circuits) fabricated thereon. The device 100 can be used to verify the characteristics of the semiconductor chips prior to dicing of the semiconductor wafer. For example, the DUT circuit 110 includes a plurality of DUTs. The switch circuit 120 is connected between the DUT circuit 110 and a test probe pad 140 and connects the DUTs to the test probe pad 140 one at a time. The control circuit 130 is connected between the switch circuit 120 and a test probe pad 150 and controls operation of the switch circuit 120 based on an input signal, e.g., input voltage signal, a clock input signal, and/or the like, applied by a signal generator 160 to the test probe pad 150. A tester 170 (e.g., a voltmeter, an ammeter, an oscilloscope, and the like) 170 may measure DUT parameters, e.g., a DUT voltage, a DUT current, and/or the like, at the test probe pad 140. The DUT parameters measured by the tester 170 can be used to verify the characteristics of the semiconductor chips.

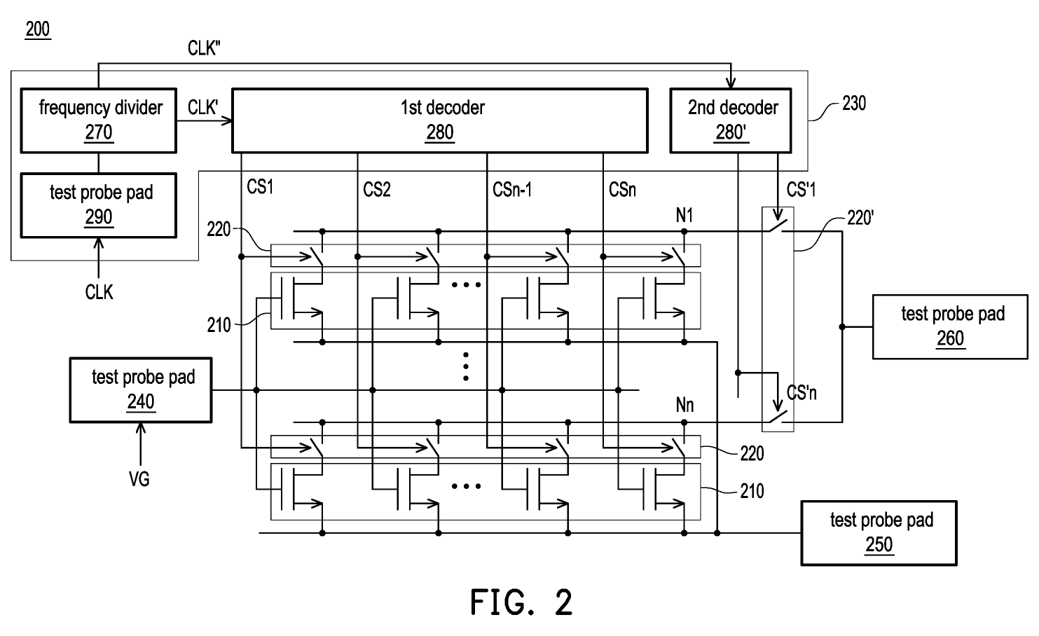

Example supporting circuitry for the device 100 is depicted in FIG. 2. It is understood that this circuitry is provided by way of example, not by limitation, and other suitable device 100 circuitry are within the scope of the present disclosure. FIG. 2 is a schematic block/circuit diagram illustrating an exemplary device 200 in accordance with various embodiments of the present disclosure. As illustrated in FIG. 2, the example device 200 includes a DUT circuit 210, a plurality of switch circuits 220, 220’, and a control circuit 230. The DUT circuit 210 includes a plurality of DUTs that are arranged in array of rows and columns. In this exemplary embodiment, each DUT is an n-type metal-oxide-semiconductor field-effect transistor (nMOSFET). In some embodiments, the DUT is a p-type metal-oxide-semiconductor field-effect transistor (pMOSFET). In other embodiments, the DUTs include one or more nMOSFETs and one or more pMOSFETs.

As further illustrated in FIG. 2, the gate terminals of the transistors are connected to each other and to a first test probe pad 240 of the device 200. The first source/drain terminals of the transistors are connected to each other and to a second test probe pad 250 of the device 200. The switch circuit 220 includes a plurality of first switches arranged in an array of rows and columns. Each of the first switches in a row has a first switch terminal connected to the second source/drain terminal of a respective one of the transistors in a corresponding row. The second switch terminals of the first switches in each row are connected to each other and to the respective DUT node (N1-Nn). In this exemplary embodiment, each first switch of the switch circuit 220 includes one or more nMOSFETs and/or one or more pMOSFETs.

The switch circuit 220’ includes a plurality of second switches, each of which has a first switch terminal connected to a respective one of the DUT nodes (N1-Nn). The second switch terminals of the second switches are connected to each other and to a test probe pad 260 of the device 200. In this exemplary embodiment, each second switch of the switch circuit 220’ includes one or more nMOSFETs and/or one or more pMOSFETs.

The control circuit 230 controls operation of the switch circuits 220, 220’ such that the DUTs of the DUT circuit 210 are connected to the test probe pad 260 one at a time. For example, the control circuit 230 includes a frequency divider 270 and first and second decoders 280, 280’. The frequency divider 270 has an input terminal that is connected to a test probe pad 290 of the device 200 and receives an input clock signal (CLK) through the test probe pad 290. The frequency divider 270 divides the clock frequency of the input clock signal (CLK) by a first predetermined factor and generates, at a first output terminal thereof, a first output clock signal (CLK’) with a clock frequency that is a fraction of the clock frequency of the input clock signal (CLK). For example, if the input clock signal (CLK) has a clock frequency of 1 MHz (i.e., a clock period of 1 microsecond) and the first predetermined factor is 128, the first output clock signal (CLK’) will have a clock period of 128 microseconds.

The first decoder 280 has an input terminal connected to the first output terminal of the frequency divider 270 and a plurality of output terminals, each of which is connected to the third switch terminals of the first switches in a respective one of the columns. The first decoder 280 receives the first output clock signal (CLK’) at the input terminal thereof, generates a plurality control signal (CS1-CSn) at the output terminals thereof based on the first output clock signal (CLK’), and shifts the control signals (CS1-CSn) at each clock period of the first output clock signal (CLK’). For example, the first decoder 280, with each clock period of the first output clock signal (CLK’), shifts the control signals (CS1-CSn) to the left (or right in other embodiments), e.g., starting from 00…0001, then to 00…0010, next to 00…0100, and finally to 10…0000, and repeats the shifting cycle thereafter.

The frequency divider 270 further divides the clock frequency of the input clock signal (CLK) by a second predetermined factor and generates, at a second output terminal thereof, a second output clock signal (CLK’’) with a clock frequency that is a fraction of the clock frequency of the input clock signal (CLK). For example, if the input clock signal (CLK) has a clock frequency of 1 MHz (i.e., a clock period of 1 microsecond) and the second predetermined factor is 256, the second output clock signal (CLK’’) will have a clock period of 256 microseconds.

The second decoder 280’ has an input terminal connected to a second output terminal of the frequency divider 270 and a plurality of output terminals, each of which is connected to the third switch terminals of the second transistors. The second decoder 280’ receives the second output clock signal (CLK’’) at the input terminal thereof, generates a plurality of control signals (CS’1-CS’n) at the output terminals thereof based on the second output clock signal (CLK’’), and shifts the control signals (CS’1-CS’n) at each clock period of the second output clock signal (CLK’’). For example, the second decoder 280’, with each clock period of the second output clock signal (CLK’’), shifts the control signals (CS’1-CS’n) to the left (or right in other embodiments), e.g., starting from 00…0001, then to 00…0010, next to 00…0100, and finally to 10…0000, and repeats the shifting cycle thereafter.

In some embodiments, the second predetermined factor is greater than the first predetermined factor. In such some embodiments, the DUTs of the DUT circuit 210 are connected to the test probe pad 260 one at a time by row. In other embodiments, the second predetermined factor is less than the first predetermined factor. In such other embodiments, the DUTs of the DUT circuit 210 are connected to the test probe pad 260 one at a time by column.

Although the transistors of the DUT circuit 210 are exemplified as arranged in an array of rows and columns, it should be understood that, after reading the present disclosure, the transistors of the DUT circuit 210 may be arranged in any manner, as long as they connected as described above.

In an exemplary operation, when it is desired to verify the characteristics of the semiconductor chips, the test probes of the signal generator 160 are attached to the test probe pads 240, 290 of the device 200, respectively, and the test probes of the tester 170 are attached to the test probe pads 250, 260, respectively. Then, the signal generator 160 applies an input voltage signal (VG) to the gate terminals of the transistors and an input clock signal (CLK) to the input terminal of the frequency divider 270, whereby the frequency divider 270 generates at the first output terminal thereof a first output clock signal (CLK’) that has a clock frequency lower than the frequency of the input clock signal (CLK) and further generates at the second output terminal thereof a second output clock signal (CLK’’) that has a clock frequency lower than the clock frequency of the first output clock signal (CLK’). Next, the first decoder 280 receives the first output clock signal (CLK’) at the input terminal thereof, generates a plurality of control signals (CS1-CSn) at the output terminals thereof, and shifts the control signals (CS1-CSn) to the left (or right) at each clock period of the first output clock signal (CLK’).

At this time, the second decoder 280’ receives the second output clock signal (CLK’’) at the input terminal thereof, generates a plurality of control signals (CS’1-CS’n) at the output terminals thereof, and shifts the control signals (CS’1-CS’n) to the left (or right) at each clock period of the second output clock signal (CLK’’). As a result, the transistors of the DUT circuit 210 are connected to the test probe pad 260 one at a time, whereby the tester 170 measures a transistor current flowing through each transistor of the DUT circuit 210. The transistor currents measured by the tester 260 can be used to verify the characteristics of the semiconductor chips.

Various configurations for the control circuit 230 are contemplated in further embodiments, so long as such various configurations achieve the intended purpose described above for the control circuit 230. For example, in such further embodiments, the control circuit 230 includes at least one of an encoder, a shift register, a multiplexer, a demultiplexer, a timer, a counter, microcontroller, or any other suitable control circuit.

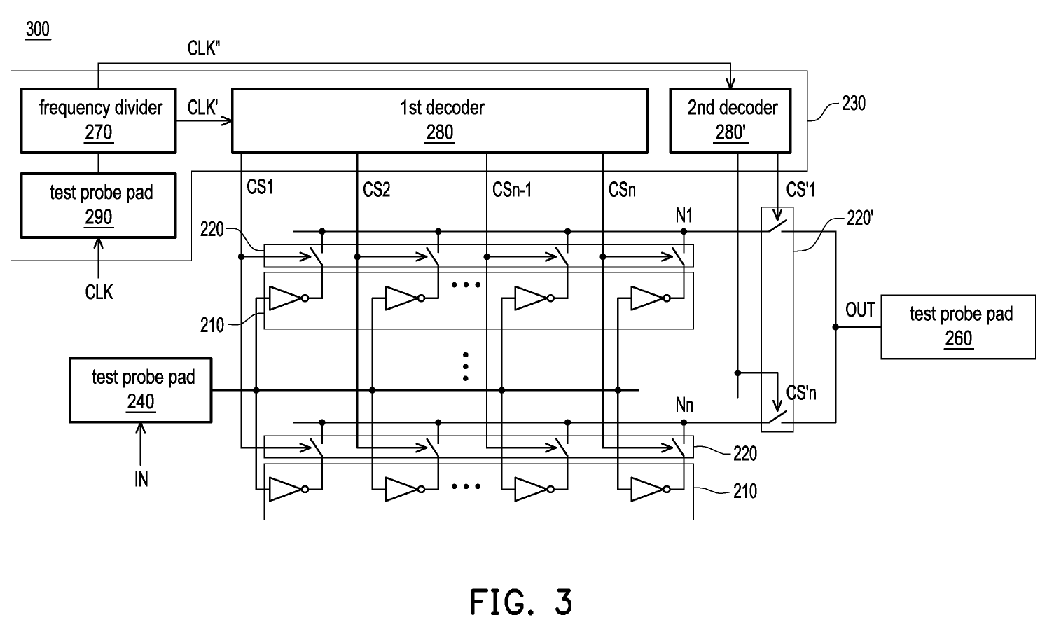

Although the DUT is exemplified in the form of a transistor, it should be understood that, after reading the present disclosure, the DUT may be another active component (such as a diode), a passive component (such as a resistor, a capacitor, or an inductor), or a DUT that includes active and passive components. For example, FIG. 3 is a schematic block/circuit diagram illustrating an exemplary device 300 in accordance with various embodiments of the present disclosure. As illustrated in FIG. 3, the example device 300 differs from the device 200 in that the DUT of the device 300 is an inverter. The input terminals of the inverters are connected to each other and to the test probe pad 240. The first switch terminal of each of the first switches in a row is connected to the output terminal of a respective one of the inverters in a corresponding row.

In an exemplary operation, when it is desired to verify the characteristics of the semiconductor chips, the test probes of the signal generator 160 are attached to the test probe pads 240, 290 of the device 200, respectively, and the test probes of the tester 170 are attached to the test probe pads 250, 260. Then, the signal generator 160 applies an input signal (IN), e.g., logical state ‘0’ or ‘1’, to the input terminals of the inverters and an input clock signal (CLK) to the input terminal of the frequency divider 270, whereby the frequency divider 270 generates at the first output terminal thereof a first output clock signal (CLK’) that has a clock frequency lower than the frequency of the input clock signal (CLK) and further generates at the second output terminal thereof a second output clock signal (CLK’’) that has a clock frequency lower than the clock frequency of the first output clock signal (CLK’). Next, the first decoder 280 receives the first output clock signal (CLK’) at the input terminal thereof, generates a plurality of control signals (CS1-CSn) at the output terminals thereof, and shifts the control signals (CS1-CSn) to the left (or right) at each clock period of the first output clock signal (CLK’).

At this time, the second decoder 280’ receives the second output clock signal (CLK’’) at the input terminal thereof, generates a plurality of control signals (CS’1-CS’n) at the output terminals thereof, and shifts the control signals (CS’1-CS’n) to the left (or right) at each clock period of the second output clock signal (CLK’’). As a result, the output terminals of the inverters are connected to the test probe pad 260 one at a time, whereby the tester 170 measures an inverter output (OUT) of each inverter of the DUT circuit 210. The inverter outputs (OUTs) measured by the tester 260 can be used to verify the characteristics of the semiconductor chips.

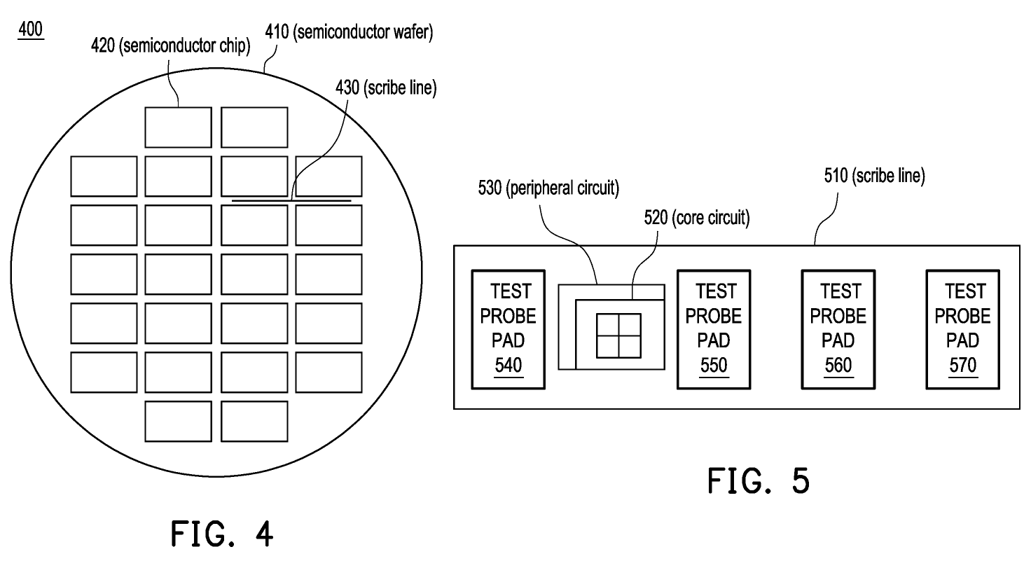

FIG. 4 is a schematic structure diagram illustrating another exemplary device 400 in accordance with various embodiments of the present disclosure. As illustrated in FIG. 4, the device 400 includes a semiconductor wafer 410, a plurality of semiconductor chips 420, one or more scribe lines 430, and a device, e.g., device 100, 200. The semiconductor chips 420 are fabricated on the semiconductor wafer 410 and includes one or more chip circuits that each perform a circuit function. The scribe line 430 serves as a demarcation between an adjacent pair of semiconductor chips 420, is etched as a narrow, shallow channels or grooves onto the surface of the semiconductor wafer 410, and penetrates a fraction of the thickness of the semiconductor wafer 410. The device 100, 200 is formed along (within or extending beyond) the scribe line 430. The device 100, 200 can be used to verify the characteristics (e.g., mismatches) of the semiconductor chips 420.

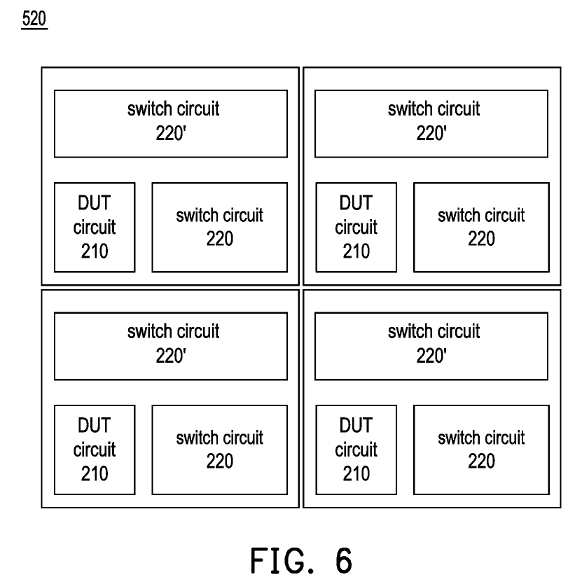

FIG. 5 is a schematic structure diagram illustrating another exemplary device in accordance with various embodiments of the present disclosure. FIG. 6 is a schematic structure diagram of exemplary core circuits 520 in accordance with various embodiments of the present disclosure. As illustrated in FIG. 5, the device, e.g., device 100, 200, is formed along (within or extending beyond) one or more scribe lines, e.g., scribe line 510, and includes a plurality of core circuits 520, a peripheral circuit 530, and a plurality of test probe pads 540-570. With further reference to FIG. 6, each core circuit 520 includes the DUT circuit 210 and the switch circuits 210, 220’. In this exemplary embodiment, the core circuits 520 are arranged in an array of rows and columns. In an alternative embodiment, the core circuits 520 are arranged along a horizontal or vertical direction.

The peripheral circuit 530 surrounds at least a portion of the core circuits 520 and includes the frequency divider 270 and the decoders 280, 280’. The test probe pads 540-570 are arranged along the length of the scribe line 510 and each corresponds to the test probe pad 240, 250, 260, or 290. In some embodiments, the core circuits 520 and the peripheral circuit 530 are between an adjacent pair of the test probe pads 540-570. In other embodiments, the core circuits 520 and the peripheral circuit 530 are at the left end of the test probe pads 540-570. In certain embodiments, the core circuits 520 and the peripheral circuit 530 are at right end of the test probe pads 540-570.

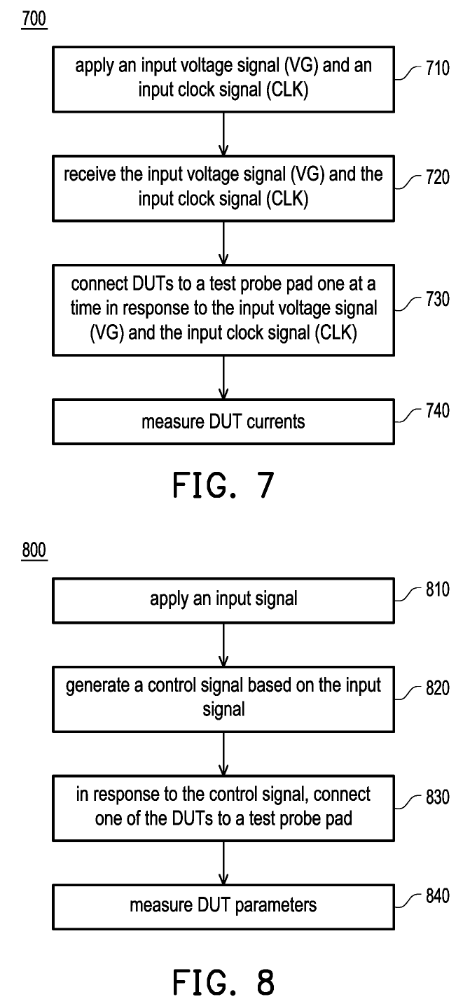

FIG. 7 is a flowchart of an exemplary method 700 for verifying the characteristics of semiconductor chips, such as those formed on a semiconductor wafer, using a device, such as that formed along (within and/or extending beyond) one or more scribe lines of the semiconductor wafer, in accordance with various embodiments of the present disclosure. The example method 700 will now be described with further reference to FIGS. 1, 2, and 4-6 for ease of understanding. It is understood that the method 700 is applicable to structures other than those of FIGS. 1, 2, and 4-6. Further, it is understood that additional operations can be provided before, during, and after the method 500, and some of the operations described below can be replaced or eliminated, in an alternative embodiment of the method 700.

In operation 710, the signal generator 160 is attached to the test probe pads 240, 290 and applies an input voltage signal (VG) to the test probe pad 240 and an input clock signal (CLK) to the test probe pads 290. In operation 720, each transistor receives the input voltage signal (VG) at the gate terminal thereof and the frequency divider 270 receives the input clock signal (CLK) at the input terminal thereof. In operation 730, the transistors are connected to the test probe pad 260 one at a time. For example, the operation 730 includes: the frequency divider 270 divides the clock frequency of the input clock signal (CLK) by a first predetermined factor, generates a first output clock signal (CLK’) at the first output terminal thereof with a clock frequency that is a fraction of the clock frequency of the input clock signal (CLK), divides the clock frequency of the input clock signal (CLK) by a second predetermined factor, and generates a second output clock signal (CLK’’) at the second output terminal thereof with a clock frequency that is a fraction of the clock frequency of the input clock signal (CLK); the decoder 280 receives the output clock signal (CLK’) at the input terminal thereof, generates a plurality of control signals (CS1-CSn) at the output terminals thereof, and shifts the control signals (CS1-CSn) at each clock period of the output clock signal (CLK’); the switch circuit 210 receives the control signals (CS1-CSn) and connects the second source/drain terminals of the transistors to the DUT node (N1) one column at a time; the decoder 280’ receives the output clock signal (CLK’’) at the input terminal thereof, generates a plurality of control signals (CS’1-CS’n) at the output terminals thereof, and shifts the control signals (CS’1-CS’n) at each clock period of the output clock signal (CLK’); and the switch circuit 210 receives the control signals (CS’1-CS’n) and connects the DUT nodes (N1-Nn) one DUT node at a time, whereby each transistor generates a transistor current that flows therethrough. In operation 740, the tester 170 is attached to the test probe pads 250, 260 and measures the transistor currents across the test probe pads 250, 260.

FIG. 8 is a flowchart of an exemplary method 800 for verifying the characteristics of semiconductor chips, such as those formed on a semiconductor wafer, using a device, such as that formed along (within and/or extending beyond) one or more scribe lines of the semiconductor wafer, in accordance with various embodiments of the present disclosure. The example method 800 will now be described with further reference to FIGS. 1 and 3 for ease of understanding. It is understood that the method 800 is applicable to structures other than those of FIGS. 1 and 3. Further, it is understood that additional operations can be provided before, during, and after the method 800, and some of the operations described below can be replaced or eliminated, in an alternative embodiment of the method 800.

In operation 810, the signal generator 160 applies an input signal (IN) to the test probe pad 150. In operation 820, the control circuit 130 receives the input signal (IN) at the input terminal thereof and generates a control signal at the output terminal thereof. In operation 830, in response to the control signal, the switch circuit 120 connects the DUTs of the DUT circuit 110 to the test probe pad 140 one at time, whereby each DUT generates a DUT parameter. In operation 840, the tester 170 measures an output at the test probe pad 140. The outputs measured by the tester 170 can be used to verify the characteristics of semiconductor chips.

In an embodiment, a device comprises a plurality of semiconductor chips, a device under test (DUT) circuit, a control circuit, and a switch circuit. The semiconductor chips are fabricated on a semiconductor wafer that includes one or more scribe lines. The DUT circuit is formed along at least one of the scribe lines and includes a plurality of DUTs. The switch circuit is connected between the DUT circuit and the control circuit. The control circuit generates a plurality of control signals. The switch circuit connects the DUTs to a test probe pad one at a time in response to the control signals.

In another embodiment, a device comprises a device under test (DUT) circuit, a control circuit, and a switch circuit connected between the DUT circuit and the control circuit. The DUT circuit includes a plurality of DUTs. The control circuit generates a plurality of control signals. The switch circuit connects the DUTs to a test probe pad one at a time in response to the control signals.

In another embodiment, a method for verifying characteristics of semiconductor chips fabricated on a semiconductor wafer that includes at least one scribe line comprises: receiving, by a device under test (DUT) circuit formed on the at least one scribe line, an input signal; generating, by the DUT circuit, a plurality of control signals based on the input signal; and connecting, by the DUT circuit, DUTs to a test probe pad one at a time in response to the control signals.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device comprising:
a plurality of semiconductor chips fabricated on a semiconductor wafer that includes one or more scribe lines;
a device under test (DUT) circuit formed along at least one of the scribe lines and including a plurality of first DUTs;
a control circuit; and a switch circuit connected between the DUT circuit and the control circuit, wherein the control circuit is configured to generate a plurality of first control signals and the switch circuit is configured to connect the first DUTs to a first test probe pad one at a time in response to the first control signals.

2. The device of claim 1, wherein:
each first DUT is a first transistor;
each first transistor has a first source/drain terminal connected to a second test probe pad; and
the switch circuit includes a plurality of first switches, each first switch having a first switch terminal connected to a second source/drain of a respective first transistor, a second switch terminal connected to a first DUT node, and a third switch terminal connected to the control circuit.

3. The device of claim 2, wherein the switch circuit further includes a third switch having a first switch terminal connected to the first DUT node, a second switch terminal connected to the first test probe pad, and a third switch terminal connected to the control circuit.

4. The device of claim 3, wherein:
the DUT circuit further includes a plurality of second DUTs;
each second DUT is a second transistor; each second transistor has a first source/drain terminal connected to the second test probe pad; and
the switch circuit further includes a plurality of second switches, each second switch having a first switch terminal connected to a second source/drain of a respective second transistor, a second switch terminal connected to a second DUT node, and a third switch terminal connected to the control circuit.

5. The device of claim 4, wherein the switch circuit further includes a fourth switch having a first switch terminal connected to the second DUT node, a second switch terminal connected to the first test probe pad, and a third switch terminal connected to the control circuit.

6. The device of claim 4, further comprising a third test probe pad connected to gate terminals of the first and second transistors and configured to receive an input voltage signal.

7. The device of claim 1, wherein the control circuit includes:
a frequency divider configured to receive an input clock signal, to divide a clock frequency of the input clock signal by a first predetermined factor, and to generate a first output clock signal; and
a first decoder configured to receive the first output clock signal, to generate a plurality of control signals, and to shift the first control signals at each clock period of the first output clock signal.

8. The device of claim 7, wherein:
the frequency divider is further configured to divide the clock frequency of the input clock signal by a second predetermined factor and to generate a second output clock signal;
the control circuit further includes a second decoder configured to receive the second output clock signal, to generate a plurality of second control signals, and to shift the second control signals at each clock period of the second output clock signal; and
the switch circuit is further configured to connect the DUTs to the test probe pad one at a time in response to the first and second control signals.

9. The device of claim 1, wherein the DUT circuit is fully within the at least one of the scribe lines.

10. The device of claim 1, further comprising:
a third test probe pad connected to the control circuit and configured to receive an input clock signal; and
a fourth test probe pad connected to the switch circuit and configured to receive an input voltage signal.

11. A device comprising:
a device under test (DUT) circuit including a plurality of first DUTs;
a control circuit; and a switch circuit connected between the DUT circuit and the control circuit, wherein the control circuit is configured to generate a plurality of first control signals and the switch circuit is configured to connect the first DUTs to a first test probe pad one at a time in response to the first control signals.

12. The device of claim 11, wherein:
each first DUT is a first transistor;
each first transistor has a first source/drain terminal connected to a second test probe pad; and
the switch circuit includes a plurality of first switches, each first switch having a first switch terminal connected to a second source/drain of a respective first transistor, a second switch terminal connected to a first DUT node, and a third switch terminal connected to the control circuit.

13. The device of claim 12, wherein the switch circuit further includes a third switch having a first switch terminal connected to the first DUT node, a second switch terminal connected to the first test probe pad, and a third switch terminal connected to the control circuit.

14. The device of claim 11, wherein the control circuit includes:
a frequency divider configured to receive an input clock signal, to divide a clock frequency of the input clock signal by a first predetermined factor, and to generate a first output clock signal; and
a first shift decoder configured to receive the first output clock signal, to generate a plurality of control signals, and to shift the first control signals at each clock period of the first output clock signal.

15. The device of claim 14, wherein:
the frequency divider is further configured to divide the clock frequency of the input clock signal by a second predetermined factor and to generate a second output clock signal;
the control circuit further includes a second decoder configured to receive the second output clock signal, to generate a plurality of second control signals, and to shift the second control signals at each clock period of the second output clock signal; and
the switch circuit is further configured to connect the DUTs to the test probe pad one at a time in response to the first and second control signals.

16. The device of claim 15, wherein the second predetermined factor is greater or less than the first predetermined factor.

17. A method for verifying characteristics of semiconductor chips fabricated on a semiconductor wafer that includes at least one scribe line, the method comprising:
receiving, by a device under test (DUT) circuit formed on the at least one scribe line, an input signal;
generating, by the DUT circuit, a plurality of first control signals based on the input signal; and
connecting, by the DUT circuit, DUTs to a test probe pad one at a time in response to the first control signals.

18. The method of claim 17, further comprising:
dividing the input signal by a first predetermined factor to generate a first output clock signal; and
shifting the first control signals at each clock period of the first output clock signal.

19. The method of claim 18, further comprising:
dividing the input signal by a second predetermined factor to generate a second output clock signal;
generating a plurality of second control signals based on the second output clock signal; and
shifting the second control signal at each clock period of the second output clock signal.

20. The method of claim 19, wherein the second predetermined factor is greater or less than the first predetermined factor.
